(19) United States
(12) Patent Application Publication
(10) Pub. No.: US 2007/0057375 A1
(43) Pub. Date: Mar. 15, 2007

(54) Multilayered wiring substrate and manufacturing method thereof

(75) Inventor: Junichi Nakamura, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 11/519,940

(22) Filed: Sep. 13, 2006

(30) Foreign Application Priority Data
Sep. 14, 2005 (JP) 2005-267434

(51) Int. Cl. H01L 23/52

(52) U.S. Cl. 257/758

(57) ABSTRACT

In a multilayered wiring substrate in which insulation layers 104A, 106A, wiring layers 105A, 108A and insulation layers 104B, 106B, wiring layers 105B, 108B are laminated on both side surfaces of a core layer 101A, respectively, the core layer 101A is constituted by insulation material 112 having no reinforcing member and copper foils 113 (pattern wiring portions 103b) formed on the both side surfaces of the insulation material 112.

### TECHNICAL FIELD

The present disclosure relates to a multilayered wiring substrate and a manufacturing method thereof and, in particular, to a multilayered wiring substrate provided with a reinforcing means for preventing war page and a manufacturing method thereof

### RELATED ART

At present, the high performance and the miniaturization of electronic devices using semiconductor devices such as semiconductor chips have been proceeded. According to such the proceeding, the semiconductor devices are also intended to be manufactured with a high density thereby to attempt the increase of the number of pins and the miniaturization. A multilayered wiring substrate utilizing the build-up method is provided as a substrate capable of mounting such the semiconductor device realizing the increase of the number of pins and the miniaturization.

This kind of the multilayered wiring substrate is configured in a manner that a reinforcing member such as a glass cloth copper laminated plate is used as core layer, and an insulation layer and a wiring layer are alternatively formed on each of the both surfaces of the core layer (see a patent document 1: Japanese Patent Unexamined Publication No. 2000-261147). FIG. 7 is a sectional diagram showing the schematic configuration of an example of such a kind of multilayered wiring substrate 10A. As shown in the figure, the multilayered wiring substrate 10A is configured that an insulation layer 13 and a wiring layer 14 are laminated on each of the both sides of a core substrate 11 at which through holes 12 are formed. The wiring layers 14 formed on the upper and lower sides of the core substrate 11 are electrically coupled via the through holes 12.

On the other hand, in recent years, in the multilayered wiring substrates utilizing the build-up method, a multilayered wiring substrate having no core layer has been developed (see a patent document 2: Japanese Patent Unexamined Publication No. Hei. 10-125818). FIG. 8 is a sectional diagram showing the schematic configuration of an example of a multilayered wiring substrate 10B having no core layer.

As shown in this figure, in the multilayered wiring substrate 10B having no core layer (hereinafter called a coreless substrate, if required), an insulation layer 13 and a wiring layer 14 are sequentially laminated on a supporting substrate 16 and then the supporting substrate 16 is removed thereby to form the multilayered wiring substrate 10B (FIG. 8 shows a state before the supporting substrate 16 is removed). In the multilayered wiring substrate 10B, at the time of forming the insulation layer 13 and the wiring layer 14, both the insulation layer 13 and the wiring layer 14 are supported by the supporting substrate 16. Further, since the supporting substrate 16 is removed after forming the insulation layer 13 and the wiring layer 14, the multilayered wiring substrate 10B can be made thin.

In the multilayered wiring substrate 10A shown in FIG. 7, since the wiring layer 14 can be formed finely, semiconductor devices manufactured with a high density can be mounted. However, the multilayered wiring substrate 10A includes the core substrate 11 therein, so that there arises a problem that the through holes 12 formed in the core substrate 11 is difficult to be formed finely and so the multilayered wiring substrate 10A can not be manufactured with a high density as a whole.

Further, in the case of forming the through holes 12 at the core substrate 11, the openings for the through holes are formed by using a drill. Thus, there arises a problem that the drilling procedure requires a long time for forming the openings for the through holes and the forming cost is high. Furthermore, since the core substrate 11 is provided, the thickness of the multilayered wiring substrate 10A becomes large inevitably and so there arises a problem that the aforesaid miniaturization of the electronic devices is impeded.

On the other hand, although the multilayered wiring substrate 10B as the coreless substrate shown in FIG. 8 can be made further thin as compared with the multilayered wiring substrate 10A shown in FIG. 7, the supporting substrate 16 is required to be removed inevitably and so there is a problem that the supporting substrate 16 is wasted. Further, since the etching process for removing the supporting substrate 16 is required in the manufacturing process of the multilayered wiring substrate 10B, there arise problems that the manufacturing process is complicated and the manufacturing efficiency is bad since it takes a long time to execute the etching process. Furthermore, since the multilayered wiring substrate 10B as the coreless substrate has no core substrate, there arises a problem that the intensity thereof is degraded and so the warpage thereof likely occurs.

### SUMMARY

Embodiments of the present invention provide a multilayered wiring substrate which can suppress the occurrence of the warpage thereof, and further provide a manufacturing method of the multilayered wiring substrate which can manufacture the multilayered wiring substrate efficiently at a low cost.

According to a first aspect of one or more embodiments of the invention, there is provided with a multilayered wiring substrate comprising a core layer, and an insulation layer and a wiring layer which are laminated on each of the both side surfaces of the core layer, the core layer includes an insulation material having no reinforcing member and copper foils formed on the both side surfaces of the insulation material, respectively.

According to the first aspect of the invention, since the reinforcing member such as a glass cloth copper laminated plate is not required, the multilayered wiring substrate can be made thin and the cost can be made low since the number of the parts can be reduced.

In the first aspect of the invention, preferably, the insulation material constituting the core layer is same as material constituting the insulation layer.

According to such a configuration, the insulation layers can be processed by the same method as that of the core layer. Further, since there is no difference of the thermal expansion coefficient between the insulation layers and the core layer, the occurrence of the warpage of the multilayered wiring substrate can be suppressed.

In the first aspect of the invention, preferably, the wiring layer includes vias for coupling the adjacent layers and a wiring pattern, and the direction of the vias of the wiring layer on one side surface of the core layer is in opposite to the direction of the vias of the wiring layer on the other side surface of the core layer.

According to such a configuration, the multilayered wiring substrate is well balanced with respect to the core layer and so the occurrence of the warpage of the multilayered wiring substrate can be suppressed.

In the first aspect of the invention, preferably, the insulation material is a build-up resin.

According to such a configuration, vias can be formed with a high density at the core layer.

In the first aspect of the invention, the copper foil may include pattern wiring portions and a reinforcing portion disposed between the adjacent pattern wiring portions.

According to such a configuration, since the reinforcing portion is formed by using portions where the pattern wiring portions are not formed, the mechanical intensity of the core layer can be enhanced.

In the first aspect of the invention, the copper foil may include pattern wiring portions and a plane-shaped wiring which acts as a power source or a ground wiring and is disposed between the adjacent pattern wiring portions.

According to such a configuration, since the plane-shaped wirings acting as the power source or the ground electrode is formed by using portions where the pattern wiring portions are not formed, the mechanical intensity of the core layer can be enhanced while improving the electric characteristics of the power source or the ground.

Further, according to a second aspect of one or more embodiments of the invention, there is provided with a method of manufacturing a multilayered wiring substrate includes a step of: sequentially laminating an insulation layer and a wiring layer on each of the both side surfaces of a core layer, wherein the wiring layer includes vias for coupling the adjacent layers and a wiring pattern, and wherein the core layer includes an insulation material and copper foils formed on the both side surfaces of the insulation material, respectively.

According to the second aspect of the invention, since the etching process for removing the supporting substrate that has been required in the coreless substrate of the related technique becomes unnecessary, the manufacturing processing can be made shorten and the manufacturing cost can be reduced. Further, since the wiring layer and the insulation layer can be sequentially laminated on the each of the both surfaces of the core layer, the multilayered wiring substrate which is well balanced and causes no warpage can be manufactured easily.

In the second aspect of the invention, via holes may be formed by using laser at the time of forming the vias.

According to this method, since the drilling procedure can be eliminated that has been required in the case of forming the openings for the through holes in the related technique, the via holes and via plug can be formed with a high-density.

Various implementations may include one or more the following advantages. For example, the thinning and the high density can be realized and the multilayered wiring substrate capable of realizing the thinning and the high density can be manufactured efficiently and easily.

Other features and advantages may be apparent from the following detailed description, the accompanying drawings and the claims.

### BRIEF DESCRIPTION OF THE DRAWINGS

FIG. 1 is a sectional diagram showing the multilayered wiring substrate according the first embodiment of the invention.

FIGS. 2A to 2G are diagrams for explaining, in accordance with the manufacturing order, the manufacturing method of the multilayered wiring substrate according the first embodiment of the invention.

FIG. 3 is a sectional diagram showing a core layer constituting the multilayered wiring substrate according the second embodiment of the invention.

FIG. 4 is a sectional diagram showing the multilayered wiring substrate according the second embodiment of the invention.

FIG. 5 is a sectional diagram showing a core layer constituting the multilayered wiring substrate according the third embodiment of the invention.

FIG. 6 is a sectional diagram showing the multilayered wiring substrate according the third embodiment of the invention.

FIG. 7 is a sectional diagram showing the multilayered wiring substrate according to an example of the related technique (No. 1)

FIG. 8 is a sectional diagram showing the multilayered wiring substrate according to an example of the related technique (No. 2)

### DETAILED DESCRIPTION

Next, the best mode for carrying out the invention will be explained with reference to drawings.

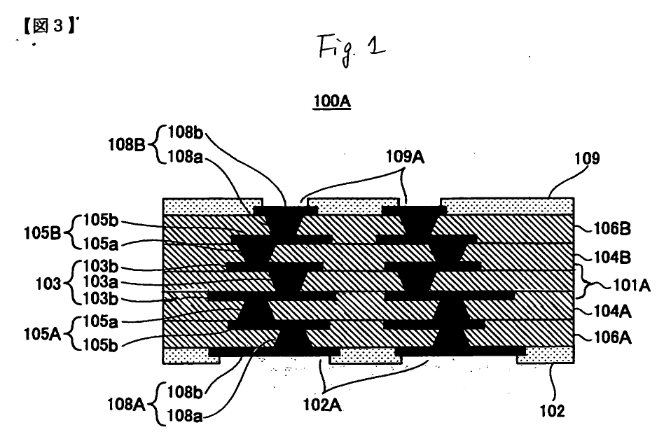

FIG. 1 shows a multilayered wiring substrate 100A according to a first embodiment of the invention. As shown in this figure, in this embodiment, the explanation will be made as to a six-layer structure as an example of the multilayered wiring substrate 100A. However, the invention is not limited to the six-layer structure and can be widely applied to multilayered wiring substrate having various numbers of layers.

In brief, the multilayered wiring substrate 100A is configured by laminating a core layer 101A, first insulation layers 104A, 104B, wiring layers 105A, 105B, second insulation layers 106A, 106B and wiring layers 108A, 108B. A solder resist 102 is formed on the lower surface of the second insulation layer 106A and a solder resist 109 is formed on the upper surface of the second insulation layer 106B.

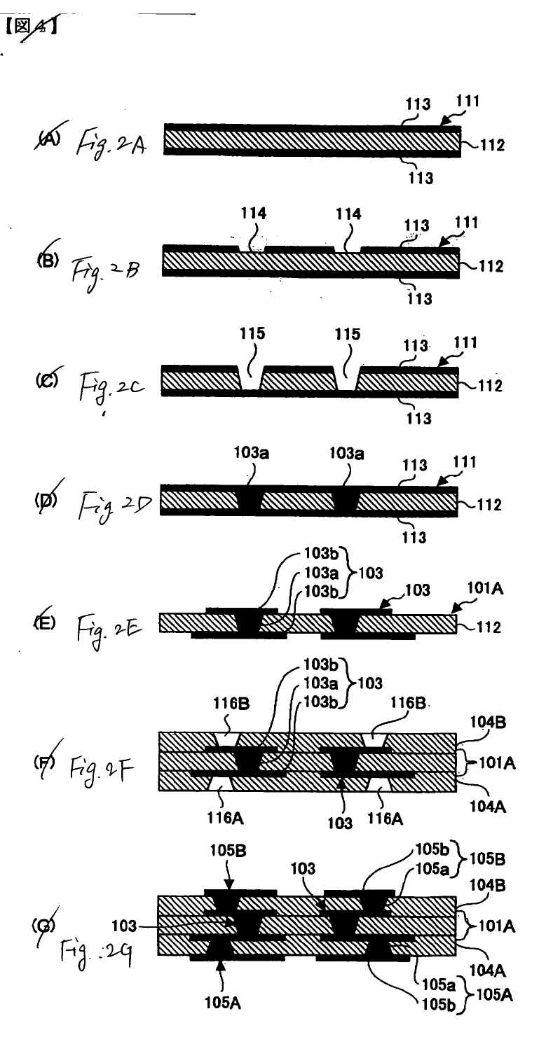

As shown in FIG. 2E, the core layer 101A is configured by an insulation material 112 and a wiring layer 103. The insulation material 112 is formed by epoxy build-up resin with the thermosetting property, for example. Further, the wiring layer 103 is formed by copper and configured by via plug portions 103a for coupling the layers and pattern wiring portions 103b for performing the coupling in the surface direction.

In this embodiment, the insulation material 112 is configured so as not to contain the reinforcing material. To be concrete, as explained with reference to FIG. 7, the core substrate 11 having been used is configured by impregnating a woven cloth such as glass cloth, aramid woven cloth, LCP woven cloth or, non-woven cloth with the build-up resin. However, the core layer 101A used in the embodiment is not constituted so as to contain the reinforcing member such as the glass cloth within the insulation material 112 but is constituted by the build-up resin.

Like the insulation material 112, each of the first insulation layers 104A, 104B and the second insulation layers 106A, 106B is formed by the epoxy build-up resin with the thermosetting property. The first insulation layers 104A, 104B are formed so as to sandwich the core layer 101A, and the second insulation layers 106A, 106B are formed so as to sandwich the core layer 101A and the first insulation layers 104A, 104B.

Each of the aforesaid respective build-up resins is not limited to one with the thermosetting property but may be other insulative resin such as build-up resin or polyimide with the photosensitivity.

In the multilayered wiring substrate 100A, the wiring layers 105A, 105B, 108A, 108B are formed as well as the core layer 101A and the respective insulation layers 104A, 104B, 106A, 106B. Each of the wiring layers 105A, 105B, 108A, 108B is formed by Cu, for example.

Each of the wiring layers 105A, 105B has the same configuration and is configured to include a via plug portion 105a and a pattern wiring portion 105b. The via plug portions 105a are formed at opening portions formed at the first insulation layers 104A, 104B, respectively, and the pattern wiring portions 105b are formed on the first insulation layers 104A, 104B, respectively. The one end of each of the via plug portions 105a is coupled to the pattern wiring portion 105b and the other end thereof is coupled to the pattern wiring portion 103b formed on the core layer 101A.

Each of the wiring layers 108A, 108B has the same configuration and is configured to include a via plug portion 108a and a pattern wiring portion 108b. The via plug portions 108a are formed at opening portions formed at the insulation layers 106A, 106B and the pattern wiring portions 108b are formed on the insulation layers 106A, 106B, respectively. The one ends of the via plug portions 108a are coupled to the pattern wiring portions 108b and the other ends thereof are coupled to the pattern wiring portions 105b formed on the wiring layers 105A, 105B, respectively.

The multilayered wiring substrate 100A configured in this manner uses the core layer 101A formed by the insulation material 112 and the wiring layer 103 in place of the core substrate 11 reinforced by the glass cloth etc. that has been required in the multilayered wiring substrate 10A of the related technique (see FIG. 7). Thus, the multilayered wiring substrate 100A can be made thin and the cost can be made low since the number of the parts can be reduced.

Further, in this embodiment, since the insulation material 112 constituting the core layer 101A is formed by the build-up material which also constitutes the insulation layers 104A, 104B, 106A, 106B, the insulation layers 104A, 104B, 106A, 106B can be processed by the same method as that of the core layer 101A.

Further, since there is no difference of the thermal expansion coefficient between the insulation layers 104A, 104B, 106A, 106B and the core layer 101A (the insulation material 112), the occurrence of the warpage of the multilayered wiring substrate 100A can be suppressed. Furthermore, since the build-up resin capable of performing the high-density processing is used for each of the insulation layers 104A, 104B, 106A, 106B, each of the via plug potions 103a, 105a, 108a can be formed with a high density as described later.

Furthermore, in the multilayered wiring substrate 100A according to the embodiment, the first insulation layer 104A, the second insulation layer 106A, the wiring layer 105A, the wiring layer 108A and the first insulation layer 104B, the second insulation layer 106B, the wiring layer 105B, the wiring layer 108B are disposed symmetrically with respect to the core layer 101A.

In particular, as described later, each of the via plug portions 105a, 108a is formed in a truncated cone shape since it is formed by plating and filling a via hole formed by the laser processing with Cu. The via plug portions 105a, 108a shaped into truncated cone are also disposed symmetrically with respect to the core layer 101A. That is, an upper face, that is smaller than a base face, of the truncated cone shape is directed to the core layer 101A so that a direction of the via plug portions on one side surface of the core layer 101A is in opposite to a direction of the via plug portions on the other side surface of the core layer 101A.

In this manner, since the configuration arranged on the upper side of the core layer and the configuration arranged on the lower side of the core layer are disposed symmetrically with respect to the core layer 101A, the multilayered wiring substrate 100A is well balanced with respect to the core layer 101A and so the occurrence of the warpage of the multilayered wiring substrate 100A can be suppressed.

Next, the explanation will be made with reference to FIGS. 2A to 2G as to the manufacturing method of the multilayered wiring substrate 100A configured in the aforesaid manner. In FIGS. 2A to 2G, like parts corresponding to those of FIG. 1 are marked with the same references.

In the case of manufacturing the multilayered wiring substrate 100A, at first, a core material 111 shown in FIG. 2A is prepared. The core material 111 is configured in a manner that copper foils 113 are disposed on the both surfaces of the insulation material 112, respectively. As described above, the insulation material 112 is formed by the epoxy build-up resin with the thermosetting property.

On the core material 111, a photo resist constituted by photosensitive resin material is formed by the screen printing method, the laminating of a photosensitive resin film, or the coating method etc. Next, light is irradiated on the photo resist through a mask pattern (not shown) to expose the photo resist, thereby performing the patterning processing to form the opening portions at the positions where the via plug portions 103a are formed, respectively, as described later.

Then, the copper foil 113 on the one surface is etched by using the photo resist thus subjected to the patterning process as a mask. Thereafter, the photo resist is exfoliated thereby to form laser openings 114 at the forming positions of the via plug portions 103a, respectively, as shown in FIG. 2B.

Succeedingly, the laser processing is executed by using the copper foil 113, at which the laser openings 114 are formed, as a mask thereby to form via openings 115 at the insulation material 112 as shown in FIG. 2C. Alternatively, the laser processing may be directly performed on the copper foil 113 thereby to form the via openings 115 at the insulation material 112.

On the surface of each of the via openings 115, a seed layer (not shown) serving as a conductive path is formed by the electroless copper plating. After the seed layer is formed, succeedingly, the electrolytic copper plating is performed thereby to form the via plug portions 103a within the via openings 115, respectively, as shown in FIG. 2D.

Succeedingly, on each of the both surfaces of the core material 111 at which the via plug portions 103a are formed, a photo resist constituted by the photosensitive resin material is formed by the screen printing method, the laminating of a photosensitive resin film, or the coating method etc. Next, light is irradiated on the photo resist through a mask pattern (not shown) to expose the photo resist, thereby performing the patterning processing to remove the photo resist except for the forming positions of the pattern wiring portions 103b.

Next, the copper foil 113 is etched by using the photo resist thus subjected to the patterning process as a mask. Thereafter, the photo resist is exfoliated thereby to form the wiring layer 103 constituted by the via plug portions 103a and the pattern wiring portions 103b as shown in FIG. 2E. In this manner, the core layer 101A is manufactured.

When the core layer 101A is formed in the aforesaid manner, the forming processing of the insulation layers 104A, 104B, 106A, 106B and the wiring layers 105A, 105B, 108A, 108B is executed by using the core layer 101A as a core. In the processings performed hereinafter, respective processings of the upper and lower layers with respect to the core layer 101A are performed integrally.

First, the first insulation layers 104A, 104B (the build-up layers) are formed on the lower and upper surfaces of the core layer 101A, respectively, by coating the epoxy resin etc. with the thermosetting property or laminating a resin film. Next, via openings 116A, 116B are formed by the laser processing at the forming positions of the via plug portions 105a of the first insulation layers 104A, 104B, respectively.

FIG. 2F shows a state where the via openings 116A, 116B are formed at the first insulation layers 104A, 104B, respectively.

Next, the wiring layers 105A, 105B are formed at the first insulation layers 104A, 104B by using the plating method. That is, the via plug portions 105a are formed at the via openings 116A, 116B of the first insulation layers 104A, 104B, respectively, and the pattern wiring portions 105b are formed on the outside surfaces of the first insulation layers 104A, 104B, respectively. In this case, each of the pattern wiring portions 105b is integrally coupled with the corresponding one of the via plug portions 105a, whereby the wiring layers 105A and 105B are formed.

To be concrete, a seed layer is formed on each of the outside surfaces of the first insulation layers 104A, 104B by the electroless plating, and then a resist pattern (not shown) corresponding to the shape of the pattern wiring portion 105b is formed by the photo lithography method. Next, Cu is precipitated by the electrolytic plating by using the resist pattern as a mask, and then the resist pattern and the unnecessary seed layer are removed. Thus, as shown in FIG. 2G, the wiring layers 105A, 105B each formed by the via plug portions 105a and the pattern wiring portions 105b are formed.

When the first insulation layers 104A, 104B and the wiring layers 105A and 105B are formed as described above, then the second insulation layers 106A, 106B and the wiring layers 108A, 108B are formed. Since the second insulation layers 106A, 106B and the wiring layers 108A, 108B are formed by the same method as that of the first insulation layers 104A, 104B and the wiring layers 105A and 105B, the explanation of the forming method thereof is omitted.

Next, solder resists 102, 109 are formed on the second insulation layers 106A, 106B by the screen printing method etc. Next, lights are irradiated on the solder resists 102, 109 through mask patterns (not shown) to expose the photo resists, thereby performing the patterning processing to form opening portions 102A, 109A, respectively. The forming positions of the opening portions 102A, 109A are set so as to be positions opposing to the corresponding pattern wiring portions 108b, respectively. Thus, in a state where the solder resists 102, 109 are formed, the pattern wiring portions 108b are placed in a state of being exposed from the opening portions 102A, 109A, respectively. Incidentally, the solder resists 102, 109 respectively having the opening portions 102A, 109A may be formed by printing the thermosetting resin material such as epoxy by using the screen printing method.

The multilayered wiring substrate 100A shown in FIG. 1 is manufactured by executing the aforesaid series of processings. According to the manufacturing method of the embodiment, since the first insulation layer 104A, the second insulation layer 106A, the wiring layer 105A, the wiring layer 108A and the first insulation layer 104B, the second insulation layer 106B, the wiring layer 105B, the wiring layer 108B are sequentially laminated on the both surfaces of the core layer 101A, respectively, the occurrence of the warpage can be suppressed. Further, since the removing procedure of the supporting substrate 16 using the etching processing that has been required in the coreless substrate 10B of the related technique (see FIG. 8) can be eliminated, the manufacturing processing can be made shorten and the manufacturing cost can be reduced.

Further, since the first insulation layer 104A, the second insulation layer 106A, the wiring layer 105A, the wiring layer 108A and the first insulation layer 104B, the second insulation layer 106B, the wiring layer 105B, the wiring layer 108B are sequentially laminated on the both surfaces of the core layer 101A, respectively, the multilayered wiring substrate 100A which is well balanced between the upper and lower sides thereof with respect to the core layer 101A and causes no warpage can be manufactured easily.

Furthermore, the via openings 115 are formed by using the laser in the case of forming the via plug portions 103a, the drilling procedure can be eliminated that has been required in the case of forming the openings for the through holes in the related technique. Thus, the via openings 115 and the via plug portions 103a can be formed with a high-density. As a result, the multilayered wiring substrate 100A can be used as a substrate for semiconductor devices and electronic devices manufactured with a high density.

The manufacturing method according to the embodiment is not so different from the manufacturing procedure of the multilayered wiring substrate that has been performed in the related art, so that the cost of the facility can be reduced and accordingly the cost of the multilayered wiring substrate 100A can be reduced. Further, according to the manufacturing method of the multilayered wiring substrate 100A of the embodiment, since the core layer 101A has almost the same thickness (for example, 0.03 to 0.1 mm) as those of the insulation layers 104A, 104B, 106A, 106B, the thinning of the multilayered wiring substrate 100A can be realized.

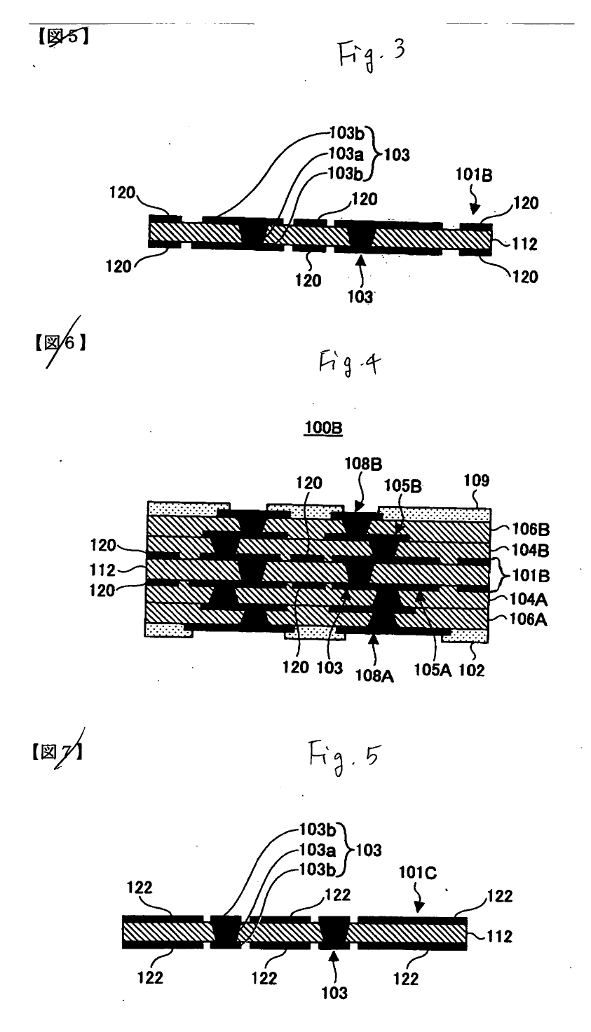

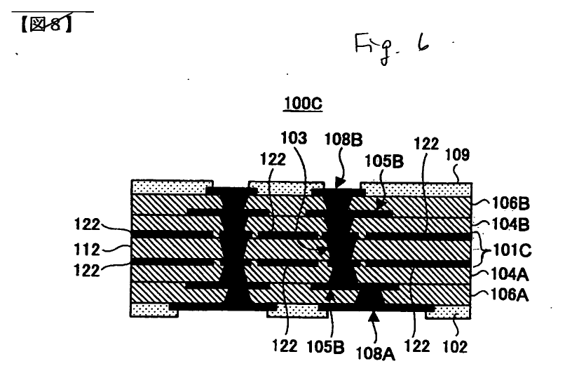

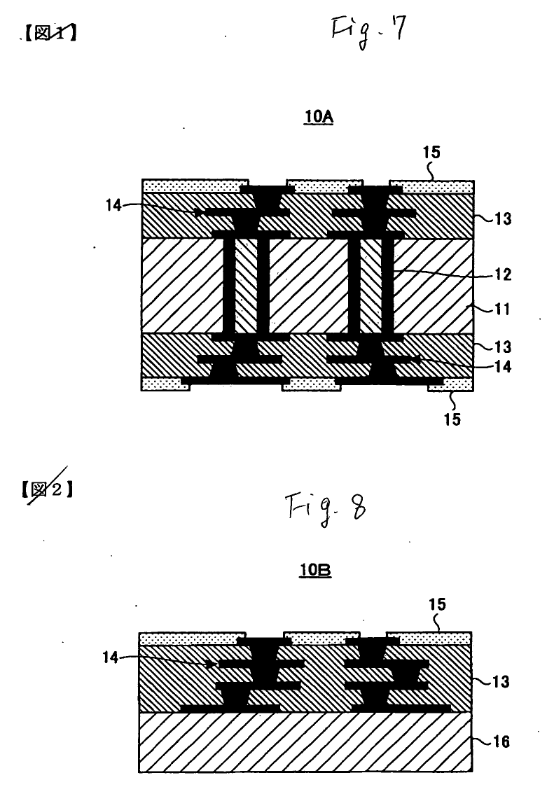

Next, the explanation will be made as to multilayered wiring substrate 100B, 100C according to the second and third embodiments of the invention, respectively. FIG. 3 shows a core layer 101B used for the multilayered wiring substrate 100B according to the second embodiment, and FIG. 4 shows the multilayered wiring substrate 100B according to the second embodiment. Further, FIG. 5 shows a core layer 101C used for the multilayered wiring substrate 100C according to the third embodiment, and FIG. 6 shows the multilayered wiring substrate 100C according to the third embodiment. In FIGS. 3 to 6, portions having the same configurations as those of the multilayered wiring substrate 100A according to the first embodiment explained with reference to FIGS. 1 to 2G are referred to by the common symbols, with explanation thereof being omitted.

The multilayered wiring substrate 100B according to the second embodiment shown in FIGS. 3 and 4 is characterized in that reinforcing portions 120 as well as the wiring layers 103 are formed at the insulation material 112 constituting the core layer 101B.

Since the reinforcing portions 120 are formed by the copper foils 113 (see FIG. 2A), the reinforcing portions can be formed simultaneously with the forming of the pattern wiring portions 103b. Further, the disposing positions of the reinforcing portions 120 are set at positions other than the preset forming positions of the pattern wiring portions 103b. Thus, the pattern wiring portions 103b are not influenced by the forming of the reinforcing portions 120. According to this configuration, since the reinforcing portions 120 are formed by using portions where the pattern wiring portions 103b are not formed, the mechanical intensity of the core layer 101B can be enhanced and so the multilayered wiring substrate 100B can be realized which has a high reliability and in which the degree of the warpage is reduced.

On the other hand, the multilayered wiring substrate 100C according to the third embodiment shown in FIGS. 5 and 6 is characterized in that plane-shaped wirings (so-called an all over pattern) as well as the wiring layers 103 are formed at the insulation material 112 constituting the core layer 101C. Although this embodiment shows an example that the plane-shaped wirings are formed as ground layers 122, the plane-shaped wirings may be formed as power source layers and, alternatively, may be configured as the mixture of the ground layers and the power source layers.

Since the ground layers 122 are also formed by the copper foils 113, the ground layers can be formed simultaneously with the forming of the pattern wiring portions 103b. Further, the disposing positions of the ground layers 122 are set at positions other than the preset forming positions of the pattern wiring portions 103b. Thus, the pattern wiring portions 103b are not influenced by the forming of the ground layers 122.

According to this configuration, since the plane-shaped wirings acting as the power source or the ground are formed by using portions where the pattern wiring portions 103b are not formed, the mechanical intensity of the core layer 101C can be enhanced while improving the electric characteristics of the power source or the ground.

Further, when the plane-shaped wirings are used as the ground layers 122, the ground layers 122 can be acted as shield layers and so the multilayered wiring substrate 100C with good high-frequency characteristics can be realized. Furthermore, since the area of the copper foils can be made large, the mechanical intensity of the core layer 101C can be enhanced and the occurrence of the warpage can be suppressed.

For the sake of simplifying the drawings, the aforesaid manufacturing method of the multilayered wiring substrate 100A is shown as to the procedure where the single multilayered wiring substrate 100A is manufactured from the single core layer 101A. However, in fact, many multilayered wiring substrates are formed from the single core layer. That is, many multilayered wiring substrates 100A are formed on the single core layer 101A, and these multilayered wiring substrates are cut out separately thereby to form the individual multilayered wiring substrates 100A. Thus, the manufacturing efficiency can be improved.

What is claimed is:

1. A multilayered wiring substrate comprising:
a core layer; and
an insulation layer and a wiring layer which are laminated on each of both side surfaces of the core layer,
wherein the core layer includes an insulation material having no reinforcing member, and copper foils formed on both side surfaces of the insulation material, respectively.

2. A multilayered wiring substrate according to claim 1, wherein the insulation material constituting the core layer is same as material constituting the insulation layer.

3. A multilayered wiring substrate according to claim 1, wherein the wiring layer includes vias for coupling the adjacent layers and a wiring pattern, and a direction of the vias of the wiring layer on one side surface of the core layer is in opposite to a direction of the vias of the wiring layer on the other side surface of the core layer.

4. A multilayered wiring substrate according to claim 1, wherein the insulation material is a build-up resin.

5. A multilayered wiring substrate according to claim 1, wherein the copper foil includes pattern wiring portions and a reinforcing portion disposed between the adjacent pattern wiring portions.

6. A multilayered wiring substrate according to claim 1, wherein the copper foil includes pattern wiring portions and a plane-shaped wiring which acts as a power source or a ground wiring and is disposed between the adjacent pattern wiring portions.

7. A method of manufacturing a multilayered wiring substrate comprising a step of:
sequentially laminating an insulation layer and a wiring layer on each of both side surfaces of a core layer,
wherein the wiring layer includes vias for coupling the adjacent layers and a wiring pattern, and
wherein the core layer includes an insulation material and copper foils formed on both side surfaces of the insulation material, respectively.

8. A method of manufacturing a multilayered wiring substrate according to claim 7, wherein via holes are formed by using laser at a time of forming the vias.

9. A method of manufacturing a multilayered wiring substrate according to claim 7, wherein the core layer includes vias in the insulation material and via holes are formed by using laser at a time of forming the vias of the core layer.
